(19) United States
(12) Patent Application Publication
(10) Pub. No.: US 2016/0005526 A1
(43) Pub. Date: Jan. 7, 2016

(54) MULTILAYER INDUCTOR, METHOD OF MANUFACTURING THE SAME, AND BOARD HAVING THE SAME

(71) Applicant: SAMSUNG ELECTRO-MECHANICS CO., LTD., Suwon-Si (KR)

(72) Inventors: Jeong Hwan IM, Suwon-Si (KR); Young Jin HA, Suwon-Si (KR)

(21) Appl. No.: 14/506,268

(22) Filed: Oct. 3, 2014

(30) Foreign Application Priority Data
Jul. 3, 2014 (KR) 10-2014-0083121

(51) Int. Cl. H01F 27/28; H01F 41/04; H05K 1/18

(52) U.S. Cl. CPC H01F 27/2804; H05K 1/18; H01F 41/041; H01F 2027/2809

(57) ABSTRACT

A multilayer inductor may include a multilayer body in which a plurality of insulating layers are stacked and of which a thickness is greater than a width; and an internal coil part formed by electrically connecting a plurality of internal coil patterns disposed on the plurality of insulating layers to each other. Side surfaces of the multilayer body opposing each other in a width direction are concave.

### CROSS-REFERENCE TO RELATED APPLICATION

This application claims the benefit of Korean Patent Application No. 10-2014-0083121 filed on Jul. 3, 2014, with the Korean Intellectual Property Office, the disclosure of which is incorporated herein by reference.

### BACKGROUND

The present disclosure relates to a multilayer inductor, a method of manufacturing the same, and a board having the same.

An inductor, an electronic component, is a representative passive element constituting an electronic circuit together with a resistor and a capacitor to remove noise. The inductor is combined with the capacitor using electromagnetic properties to constitute a resonance circuit amplifying a signal in a specific frequency band, a filter circuit, or the like.

The inductor generally includes a multilayer body formed of an insulating material or a magnetic material, an internal coil part formed inside the multilayer body, and external electrodes disposed on surfaces of the multilayer body to be connected to the internal coil part.

The inductor may be mounted on a circuit board, and may be electrically connected to mounting pads on the circuit board through soldering at the time of being mounted on the circuit board, and the mounting pads may be connected to other external circuits through wiring patterns on the circuit board or conductive vias.

In the case in which the inductor is misaligned at the time of being mounted on the circuit board, a mounting defect may occur. In addition, a short-circuit may occur due to a contact with an adjacent electronic component.

### RELATED ART DOCUMENT

(Patent Document 1) Korean Patent Laid-Open Publication No. 2011-0128554

### SUMMARY

An exemplary embodiment in the present disclosure may provide a multilayer inductor, a method of manufacturing the same, and a board having the same.

According to exemplary embodiment in the present disclosure, a multilayer inductor may include: a multilayer body in which a plurality of insulating layers are stacked and of which a thickness is greater than a width; and an internal coil part formed by electrically connecting a plurality of internal coil patterns disposed on the plurality of insulating layers to each other, wherein side surfaces of the multilayer body opposing each other in a width direction are concave, and a board having the same may be provided.

According to another aspect of the present disclosure, a method of manufacturing a multilayer inductor may include: preparing a plurality of insulating sheets having different sintering shrinkage rates; forming internal coil patterns on the insulating sheets; forming an insulating sheet multilayer body by stacking the insulating sheets having the internal coil patterns formed thereon; and forming a multilayer body by sintering the insulating sheet multilayer body, wherein, in the forming of the insulating sheet multilayer body, insulating sheets having a relatively high sintering shrinkage rate are disposed adjacent to a central portion of the insulating sheet multilayer body in a thickness direction as compared with insulating sheets having a relatively low sintering shrinkage rate.

### BRIEF DESCRIPTION OF DRAWINGS

The above and other aspects, features and advantages of the embodiments in present disclosure will be more clearly understood from the following detailed description taken in conjunction with the accompanying drawings, in which:

FIG. 1 is a perspective view of a multilayer inductor according to an exemplary embodiment in the present disclosure;

FIG. 2 is an exploded perspective view of a multilayer body constituting a multilayer inductor according to an exemplary embodiment in the present disclosure;

FIG. 3 is a cross-sectional view taken along line A-A′ of FIG. 1;

FIG. 4 is a cross-sectional view taken along line B-B′ of FIG. 1;

FIG. 5 is a flowchart illustrating a method of manufacturing a multilayer inductor according to another exemplary embodiment in the present disclosure;

FIG. 6 is a perspective view schematically illustrating a board having a multilayer inductor according to another exemplary embodiment in the present disclosure; and

FIG. 7 is a cross-sectional view taken along line C-C′ of FIG. 6.

### DETAILED DESCRIPTION

Exemplary embodiments in the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Multilayer Inductor

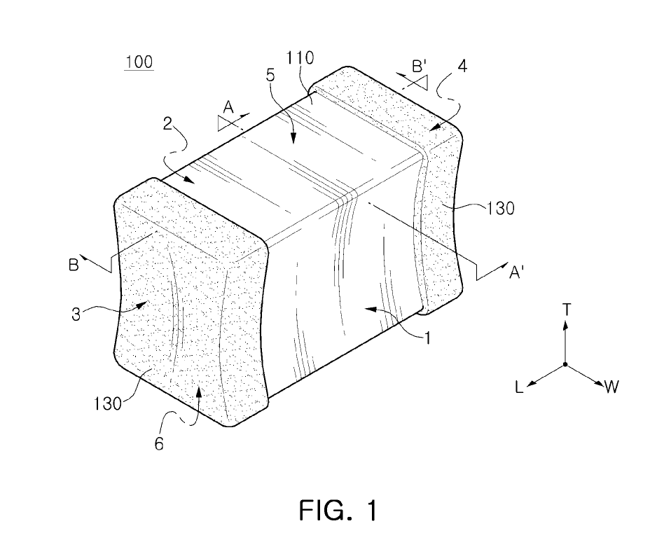

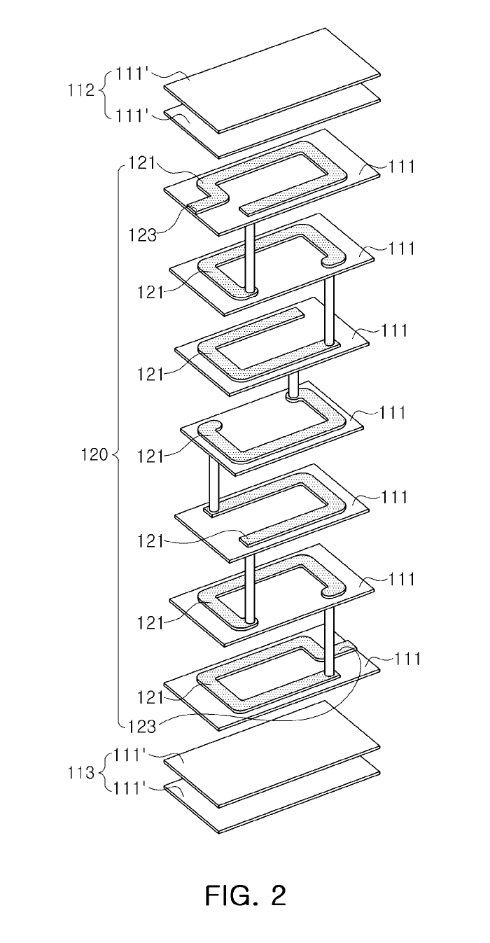

FIG. 1 is a perspective view of a multilayer inductor according to an exemplary embodiment in the present disclosure; and FIG. 2 is an exploded perspective view of a multilayer body constituting a multilayer inductor according to an exemplary embodiment in the present disclosure.

Referring to FIGS. 1 and 2, a multilayer inductor 100 according to an exemplary embodiment in the present disclosure may include a multilayer body 110, an internal coil part 120, and external electrodes 130.

The multilayer body 110 may be formed by stacking a plurality of insulating layers 111 and 111′, and a shape and a dimension of the multilayer body 110 and the number of stacked insulating layers are not limited to those illustrated in FIGS. 1 and 2.

The plurality of insulating layers 111 and 111′ forming the multilayer body 110 may be in a sintered state, and adjacent insulating layers may be integrated with each other so that boundaries therebetween are not readily apparent.

The multilayer body 110 may have a hexahedral shape. Directions of a hexahedron will be defined in order to clearly describe exemplary embodiments in the present disclosure. L, W and T shown in FIG. 1 refer to a length direction, a width direction, and a thickness direction, respectively.

In the present exemplary embodiment, for convenience of explanation, upper and lower surfaces 5 and 6 of the multilayer body 110 refer to two surfaces of the multilayer body 110 opposing each other in the thickness direction, first and second side surfaces 1 and 2 thereof refer to two surface thereof connecting the upper and lower surfaces to each other and opposing each other in the width direction, and third and fourth end surfaces 3 and 4 thereof refer to two surfaces thereof vertically intersecting the first and second side surfaces and opposing each other in the length direction.

The upper and lower surfaces of the multilayer body 110 may be understood as one surface and the other surface thereof in the thickness direction, unless specifically marked.

The multilayer body 110 may contain a magnetic material.

For example, the multilayer body 110 may contain Mn—Zn-based ferrite, Ni—Zn-based ferrite, Ni—Zn—Cu-based ferrite, Mn—Mg-based ferrite, Ba-based ferrite, or Li-based ferrite. However, the multilayer body 110 is not limited to containing the above-mentioned ferrite, but may contain various known magnetic materials.

Internal coil patterns 121 for forming the internal coil part 120 may be formed on one surfaces of the insulating layers 111, and conductive vias may be formed to penetrate through the insulating layers in the thickness direction in order to electrically connect the internal coil patterns positioned above and below each other.

Therefore, one ends of the internal coil patterns 121 formed on respective insulating layers 111 may be electrically connected to each other through the conductive vias formed in insulating layers adjacent thereto to form the internal coil part 120.

The internal coil patterns 121 may be formed by printing a conductive paste containing a conductive metal at a predetermined thickness on the plurality of insulating layers forming the multilayer body 110.

The vias may be formed at predetermined positions in respective insulating layers 111 on which the internal coil patterns 121 are printed, and the internal coil patterns 121 formed on the insulating layers may be electrically connected to each other through the vias to form a single internal coil part 120.

The conductive metal forming the internal coil patterns 121 is not particularly limited as long as it has excellent electrical conductivity. For example, the conductive metal may be at least one selected from the group consisting of silver (Ag), palladium (Pd), aluminum (Al), nickel (Ni), titanium (Ti), gold (Au), copper (Cu), platinum (Pt), and alloys thereof. Considering electrical conductivity improvement and a reduction in manufacturing costs, copper (Cu) may be used as the conductive metal.

Two of the plurality of internal coil patterns 121 forming the internal coil part 120 may include lead parts 123 led to the outside of the multilayer body in order to be connected to the external electrodes.

The insulating layers 111′ on which the internal coil patterns are not formed may be disposed on one side and the other side of the internal coil part in the stacked direction of the insulating layers 111 on which the internal coil patterns are formed.

The insulating layers 111′ on which the internal coil patterns are not formed may be disposed above and below the internal coil part 120 to form an upper cover part 112 and a lower cover part 113.

The external electrodes 130 may be formed on the outer surfaces of the multilayer body 110 to be connected to the lead parts 123 of the internal coil part 120 exposed to both end surfaces of the multilayer body 110, respectively.

For example, the external electrodes 130 may be formed on the third and fourth end surfaces of the multilayer body 110, respectively, and be extended to the upper and lower surfaces 5 and 6 and/or the first and second side surfaces 1 and 2 of the multilayer body 110.

The external electrodes 130 may be formed of a metal having excellent electrical conductivity, for example, nickel (Ni), copper (Cu), tin (Sn), silver (Ag), or an alloy thereof.

As shown in FIG. 1, in order to generate high inductance in the multilayer inductor according to the exemplary embodiment in the present disclosure, a thickness T of the multilayer body 110 may not be substantially the same as a width W thereof, but may be greater than the width W thereof.

According to the exemplary embodiment in the present disclosure, the upper surface 5 or the lower surface 6 of the multilayer body may be a mounting surface of the multilayer inductor adjacent to and facing a printed circuit board when the multilayer inductor is mounted on the printed circuit board.

At the time of being mounted on the board, the multilayer inductor 100 according to the exemplary embodiment in the present disclosure may secure a sufficient space and generate high inductance due to an increase in the thickness of the multilayer body 110.

In the case in which the thickness of the multilayer body 110 is greater than the width thereof as in the exemplary embodiment in the present disclosure, even when a mounting area occupied by the multilayer inductor in the board at the time of mounting the multilayer inductor on the board is not increased, a relatively high inductance may be secured. However, due to a rise in the center of gravity of the multilayer inductor, a chip may be inclined in a taping pocket and not picked up during a pick-up process, and an occurrence frequency of a chip collapse phenomenon during a mounting process may be increased.

In addition, when the multilayer inductor is mounted on the board, mounting defects, such as the chip collapse phenomenon, the dislocation of the multilayer inductor, or the like, may occur in a reflow process, or after mounting the multilayer inductor on the board. In the case in which the mounting defects occur, the multilayer inductor may contact an electronic component adjacent thereto, resulting in short-circuiting.

According to the exemplary embodiment in the present disclosure, a central portion of the multilayer body 110 in the thickness direction may be concave to solve the above-mentioned problem.

For example, a cross-sectional area of a length-width cross section of an upper portion or a lower portion of the multilayer body 110 in the thickness direction may be greater than a cross-sectional area of a length-width cross section of a central portion of the multilayer body 110 in the thickness direction.

For example, when the multilayer body 110 is trisected in the thickness direction, a volume of the upper or lower portion of the multilayer body 110 in the thickness direction may be greater than a volume of the central portion of the multilayer body 110 in the thickness direction.

Sintering shrinkage rates of insulating layers included in the upper or lower portion of the multilayer body 110 in the thickness direction may be different from sintering shrinkage rates of insulating layers included in the central portion of the multilayer body 110 in the thickness direction.

For example, the sintering shrinkage rates of the insulating layers 111 included in the upper and lower portions of the multilayer body 110 in the thickness direction may be lower than the sintering shrinkage rates of the insulating layers 111 included in the central portion of the multilayer body 110 in the thickness direction.

For example, as the insulating layers become closer to the center of the multilayer body 110 in the thickness direction, the sintering shrinkage rates thereof may be increased. That is, the shrinkage rates of the insulating layers disposed in the multilayer body are increased in a direction toward the center of the multilayer body in the thickness direction.

Therefore, even in the case that the three portions of the multilayer body in the thickness direction have substantially the same widths and lengths before being sintered, the central portion of the multilayer body in the thickness direction may be formed to be concave due to a difference between the sintering shrinkage rates after being sintered.

According to the exemplary embodiment in the present disclosure, the central portion of the multilayer body 110 in the thickness direction may become concave and the upper and lower portions of the multilayer body 110 in the thickness direction, adjacent to the upper and lower surfaces, one of which becomes the mounting surface at the time of mounting the multilayer inductor on the board, may be wider than the central portion of the multilayer body 110 in the thickness direction, whereby mounting stability of the multilayer inductor may be improved.

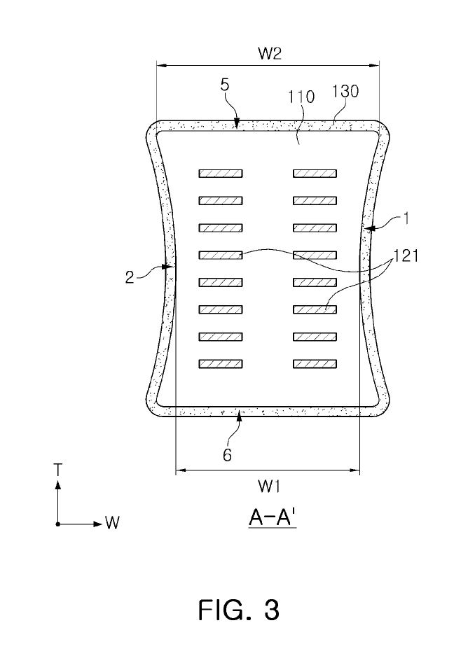

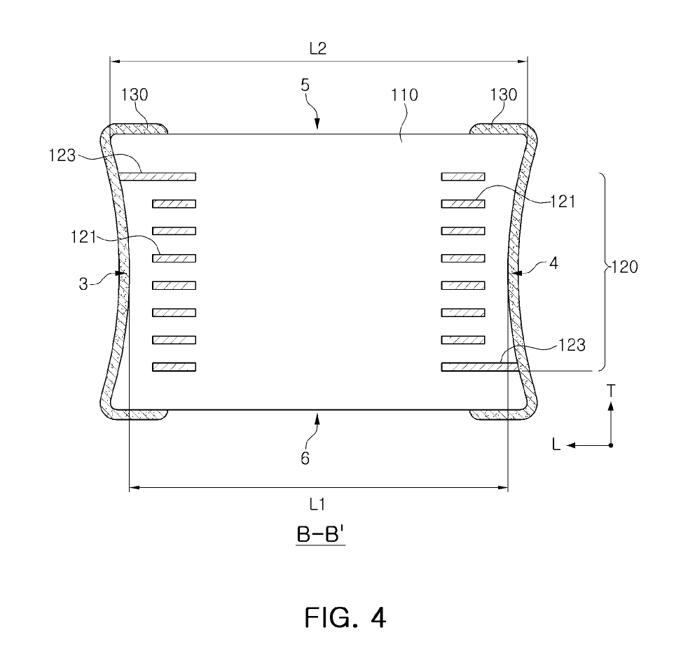

FIG. 3 is a cross-sectional view taken along line A-A′ of FIG. 1; and FIG. 4 is a cross-sectional view taken along line B-B′ of FIG. 1.

Referring to FIG. 3, the first and second side surfaces 1 and 2 of the multilayer body 110 opposing each other in the width direction may be concave.

When a width of the central portion of the multilayer body 110 in the thickness direction is W1 and a width of the upper or lower portion of the multilayer body in the thickness direction is W2, 1.01≦W2/W1≦1.3 may be satisfied.

Referring to FIG. 4, the third and fourth end surfaces 3 and 4 of the multilayer body 110 opposing each other in the length direction may be concave.

When a length of the central portion of the multilayer body 110 in the thickness direction is L1 and a length of the upper or lower portion of the multilayer body in the thickness direction is L2, 1.01≦L2/L1≦1.3 may be satisfied.

In the case in which W2/W1 is less than 1.01, amounting stability improvement effect of the multilayer inductor may not be obtained. As a result, a mounting defect that a chip collapses or is rotated may occur. In the case in which W2/W1 exceeds 1.3, delamination may occur in the multilayer body due to a shrinkage rate difference between the central portion and the upper or lower portion of the multilayer body in the thickness direction.

In the case in which L2/L1 is less than 1.01, amounting stability improvement effect of the multilayer inductor may not be obtained. As a result, a mounting defect that a chip collapses or is rotated may occur. In the case in which L2/L1 exceeds 1.3, delamination may occur in the multilayer body due to a shrinkage rate difference between the central portion and the upper or lower portion of the multilayer body in the thickness direction.

More preferably, 1.05≦W2/W1≦1.3 and 1.05≦L2/L1≦1.3 may be satisfied in order to improve the mounting stability.

In the case in which the volume of the upper or lower portion of the multilayer body 110 in the thickness direction is greater than the volume of the central portion of the multilayer body 110 in the thickness direction as in the exemplary embodiment in the present disclosure, the mounting defect such as the collapse or rotation of the chip occurring at the time of mounting the multilayer inductor on the board may be decreased, whereby the mounting stability may be improved.

### Method of Manufacturing Multilayer Inductor

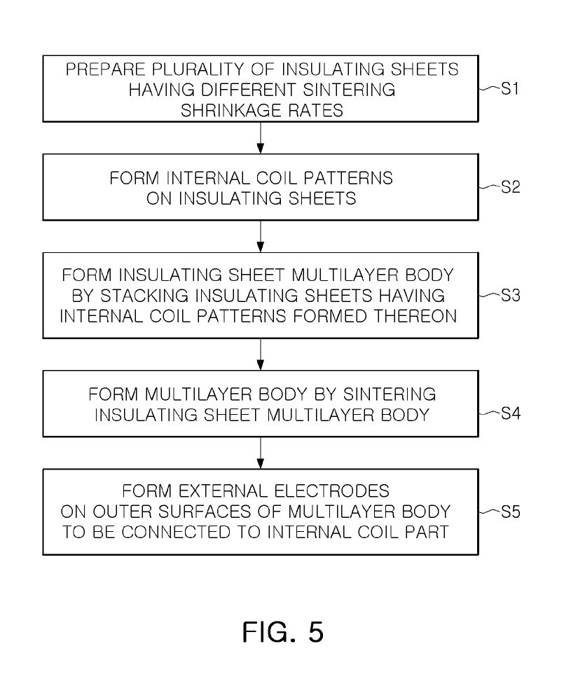

FIG. 5 is a flowchart illustrating a method of manufacturing a multilayer inductor according to another exemplary embodiment in the present disclosure.

Referring to FIG. 5, a method of manufacturing a multilayer inductor according to another exemplary embodiment in the present disclosure may include: preparing a plurality of insulating sheets (S1), forming the internal coil patterns on the insulating sheets (S2), forming an insulating sheet multilayer body by stacking the insulating sheets (S3), and forming the multilayer body by sintering the insulating sheet multilayer body (S4).

According to the exemplary embodiment in the present disclosure, the method of manufacturing a multilayer inductor may further include forming external electrodes after the forming (S4) of the multilayer body.

Hereinafter, the method of manufacturing a multilayer inductor according to the exemplary embodiment in the present disclosure will be described in more detail. However, the present disclosure is not necessarily limited thereto.

First, a plurality of insulating sheets having different sintering shrinkage rates may be prepared (S1). All of the plurality of insulating sheets do not need to have different sintering shrinkage rates. That is, two or more insulating sheets may have the same sintering shrinkage rate.

The sintering shrinkage rate of the insulating sheet may be controlled by a content of a material forming the insulating sheet, but is not limited thereto.

An insulating material for the insulating sheet is not particularly limited, but may include a magnetic material. The magnetic material is not particularly limited. For example, the magnetic material may be a powder containing ferrite known in the art such as Mn—Zn-based ferrite, Ni—Zn-based ferrite, Ni—Zn—Cu-based ferrite, Mn—Mg-based ferrite, Ba-based ferrite, Li-based ferrite, or the like, but is not limited thereto.

For example, a slurry prepared by mixing the magnetic material with an organic material may be applied to carrier films and then dried to prepare the plurality of insulating sheets.

Next, the internal coil patterns may be formed on the insulating sheets (S2).

The internal coil patterns may be formed by applying a conductive paste containing a conductive metal to the insulating sheets by a printing method, or the like. As a method of printing the conductive paste, a screen printing method, a gravure printing method, or the like, may be used. However, the present disclosure is not limited thereto.

The conductive metal is not particularly limited as long as it has excellent electrical conductivity. For example, the conductive metal may be at least one selected from the group consisting of silver (Ag), palladium (Pd), aluminum (Al), nickel (Ni), titanium (Ti), gold (Au), copper (Cu), platinum (Pt), or alloys thereof. Considering electrical conductivity improvement and a decrease in manufacturing costs, copper (Cu) may be used as the conductive metal.

Next, the insulating sheet multilayer body may be formed by stacking the insulating sheets having the internal coil patterns formed thereon (S3). The insulating sheets may be stacked such that insulating sheets having a relatively high sintering shrinkage rate are disposed at a central portion of the insulating sheet multilayer body in the thickness direction and insulating sheets having a relatively low sintering shrinkage rate are disposed at upper and lower portions of the insulating sheet multilayer body in the thickness direction. The insulating sheet multilayer body may be formed to have a uniform length and a uniform width in the thickness direction, before being sintered.

When a ratio of the width of the sintered insulating sheets disposed in the central portion of the insulating sheet multilayer body in the thickness direction to the width of the non-sintered insulating sheets disposed in the central portion of the insulating sheet multilayer body in the thickness direction is S1, and a ratio of the width of the sintered insulating sheets disposed in the upper or lower portion of the insulating sheet multilayer body in the thickness direction to the width of the non-sintered insulating sheets disposed in the upper or lower portion of the insulating sheet multilayer body in the thickness direction is S2, 1.01≦S2/S1≦1.3 may be satisfied.

In the case in which S2/S1 is less than 1.01, a difference between the sintering shrinkage rates may be insignificant, such that a mounting stability improvement effect of the multilayer inductor after being sintered may not be obtained. In the case in which S2/S1 exceeds 1.3, delamination or cracks may occur in the multilayer body during sintering the multilayer body due to a difference between the sintering shrinkage rates.

More preferably, 1.05≦S2/S1≦1.3 may be satisfied.

For example, the sintering shrinkage rate of the insulating sheet may be defined as a ratio of the difference between the width of the sintered insulating sheet and the width of the non-sintered insulating sheet to the width of the non-sintered insulating sheet.

Then, the multilayer body may be formed by sintering the insulating sheet multilayer body (S4).

In the case in which the insulating sheet multilayer body formed by stacking the insulating sheets containing the ferrite is sintered under reducing atmosphere, magnetic characteristics may deteriorate due to the reduction of the ferrite. Therefore, the insulating sheet multilayer body may be sintered under weak reducing atmosphere. A sintering temperature may be 850° C. to 1100° C., but is not limited thereto.

Next, the external electrodes 130 connected to the lead parts 123 of the internal coil part 120 may be formed on end surfaces of the sintered multilayer body 110, respectively.

The external electrodes 130 may be formed of a conductive paste containing a metal having excellent electrical conductivity, for example, a conductive paste containing nickel (Ni), copper (Cu), tin (Sn), silver (Ag), or an alloy thereof. The external electrodes 130 may be formed by a printing method, a dipping method, or the like, depending on the shape thereof.

A description of features the same as those of the multilayer inductor according to the previous exemplary embodiment in the present disclosure will be omitted.

### Board Having Multilayer Inductor

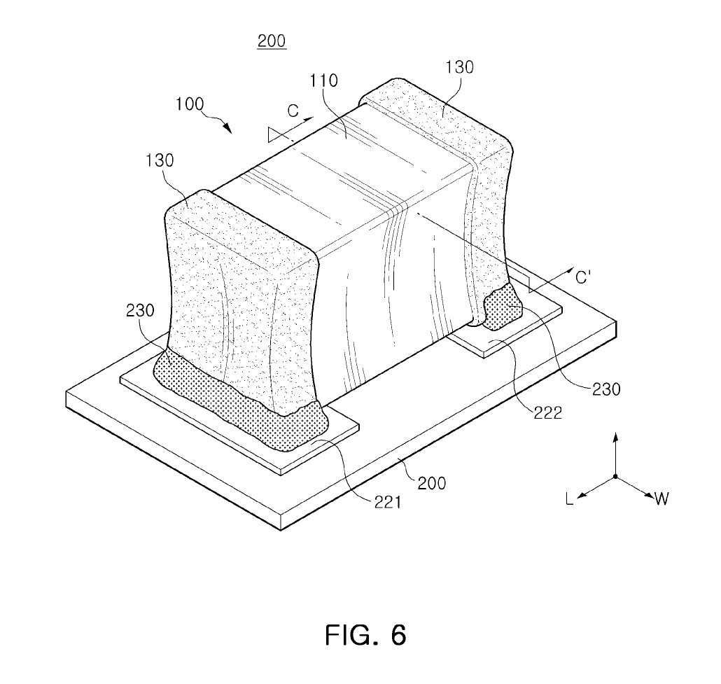

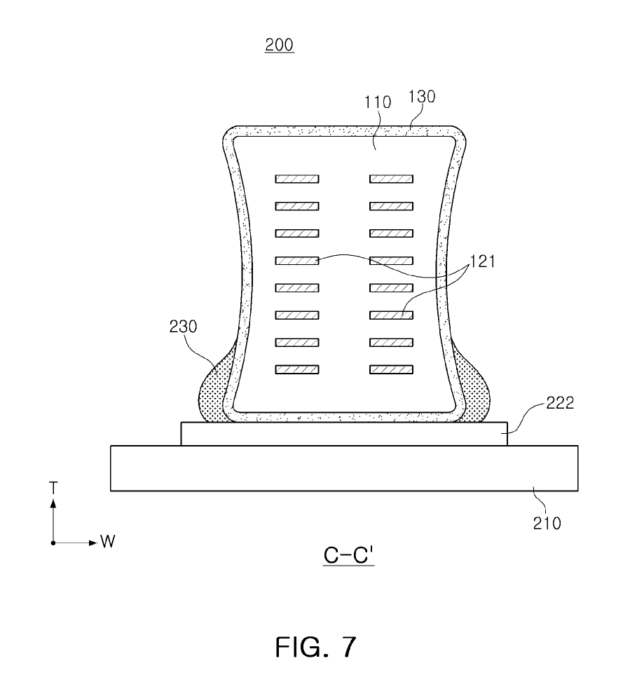

FIG. 6 is a perspective view schematically illustrating a board having a multilayer inductor according to another exemplary embodiment in the present disclosure; and FIG. 7 is a cross-sectional view taken along line C-C′ of FIG. 6.

Referring to FIGS. 6 and 7, a board 200 having a multilayer inductor according to the present exemplary embodiment may include a multilayer inductor 100 and a printed circuit board 210 on which the multilayer inductor 100 is mounted. Electrode pads 221 and 222 may be formed on an upper surface of the printed circuit board 210.

The multilayer inductor 100 may be the multilayer inductor according to the previous exemplary embodiment in the present disclosure. Therefore, a detailed description of the multilayer inductor 100 will be omitted in order to avoid redundancy.

The electrode pads 221 and 222 may be first and second electrode pads 221 and 222 connected to the external electrodes 130 of the multilayer inductor 100, respectively.

Here, the external electrodes 130 of the multilayer inductor 100 may be electrically connected to the printed circuit board 210 by solders 230 in a state in which they are positioned to contact the first and second electrode pads 221 and 222, respectively.

As shown in FIGS. 6 and 7, in the case in which the central portion of the multilayer body is concave, the volume of the upper or lower portion of the multilayer body in the thickness direction is greater than the volume of the central portion of the multilayer body in the thickness direction as in the exemplary embodiment in the present disclosure, whereby the mounting surface facing the printed circuit board may be relatively increased, and mounting stability of the multilayer inductor at the time of being mounted on the printed circuit board may be improved.

### Experimental Example

The following Table 1 shows data relating to whether or not a mounting defect of the multilayer inductor at the time of being mounted on the board and delamination of the multilayer body have occurred, depending on a ratio (W2/W1) of the width W2 of the upper or lower portion of the multilayer body to the width W1 of the central portion of the multilayer body.

The size of the multilayer inductor according to the present Experimental Example was about 0.6 mm×0.3 mm×0.6 mm (length×width×thickness), and the length and the width thereof were measured based on the bottom of the multilayer inductor.

An insulating sheet multilayer body, used to manufacture the multilayer inductor according to the present Experimental Example, was manufactured to have a uniform length and a uniform width in the thickness direction before being sintered, and the width of the insulating sheet multilayer body was varied depending on W2/W1 values of the following Table 1 using a difference between shrinkage rates of the insulating sheets after being sintered.

In the present Experimental Example, it may be understood that a ratio of the sintering shrinkage rate of the upper or lower portion of the multilayer body to the sintering shrinkage rate of the central portion of the multilayer body is the same as the ratio (W2/W1) of the width W2 of the upper or lower portion of the multilayer body to the width W1 of the central portion of the multilayer body.

The upper portion, the lower portion, and the central portion of the multilayer body may be distinguished from each other by trisecting the multilayer body in the thickness direction. In the present Experimental Example, the width W2 of the upper or lower portion of the multilayer body was measured with respect to the widest portion in the upper and lower portions of the multilayer body, and the width W1 of the central portion of the multilayer body was measured with respect to the narrowest portion in the central portion of the multilayer body.

In the following Table 1, in the case in which the multilayer inductor collapsed, was inclined, or was dislocated at the time of being mounted on the board, it was determined that a mounting defect occurred. In addition, it was determined whether delamination occurred by observing the cross section of the multilayer body in a width-thickness direction after sintering the multilayer body.

TABLE 1

| Sample | W2/W1 | Mounting Defect | Delamination |
|---|---|---|---|
| 1* | 0.95 | x | ∘ |
| 2* | 1 | x | ∘ |
| 3 | 1.05 | ∘ | ∘ |
| 4 | 1.1 | ∘ | ∘ |
| 5 | 1.15 | ∘ | ∘ |
| 6 | 1.2 | ∘ | ∘ |
| 7 | 1.25 | ∘ | ∘ |
| 8 | 1.3 | ∘ | ∘ |
| 9* | 1.35 | ∘ | x |
| 10* | 1.4 | ∘ | x |

*indicates Comparative Examples
∘: Mounting defect not occurred and delamination not occurred
x: Mounting defect occurred and delamination occurred

Referring to Table 1, it can be seen that in Samples 1 and 2 in which W2/W1 is less than 1.01, a mounting defect occurred, and in Samples 9 and 10 in which W2/W1 exceeds 1.3, a mounting defect did not occur, but delamination occurred.

As set forth above, according to exemplary embodiments in the present disclosure, a multilayer inductor having excellent mounting stability by decreasing a chip collapse phenomenon at the time of being mounted on a board and, and a method of manufacturing the same, and a board having the same may be provided.

While exemplary embodiments have been shown and described above, it will be apparent to those skilled in the art that modifications and variations could be made without departing from the scope of the present invention as defined by the appended claims.

What is claimed is:

1. A multilayer inductor comprising:
a multilayer body in which a plurality of insulating layers are stacked and of which a thickness is greater than a width; and
an internal coil part formed by electrically connecting a plurality of internal coil patterns disposed on the plurality of insulating layers to each other,
wherein side surfaces of the multilayer body opposing each other in a width direction are concave.

2. The multilayer inductor of claim 1, wherein when a width of a central portion of the multilayer body in a thickness direction is W1 and a width of an upper or lower portion of the multilayer body in the thickness direction is W2, 1.01≦W2/W1≦1.3 is satisfied.

3. The multilayer inductor of claim 1, wherein when a width of a central portion of the multilayer body in a thickness direction is W1 and a width of an upper or lower portion of the multilayer body in the thickness direction is W2, 1.05≦W2/W1≦0.3 is satisfied.

4. The multilayer inductor of claim 1, wherein end surfaces of the multilayer body opposing each other in a length direction are concave.

5. The multilayer inductor of claim 1, wherein when a length of a central portion of the multilayer body in a thickness direction is L1 and a length of an upper or lower portion of the multilayer body in the thickness direction is L2, 1.01≦L2/L1≦1.3 is satisfied.

6. The multilayer inductor of claim 1, wherein insulating layers included in upper and lower portions of the multilayer body in a thickness direction and insulating layers included in a central portion of the multilayer body in the thickness direction have different sintering shrinkage rates.

7. The multilayer inductor of claim 1, wherein sintering shrinkage rates of the insulating layers disposed in the multilayer body are increased in a direction toward a center of the multilayer body in a thickness direction.

8. A multilayer inductor comprising:
a multilayer body in which a plurality of insulating layers are stacked and of which a thickness is greater than a width;
an internal coil part formed by electrically connecting a plurality of internal coil patterns disposed on the plurality of insulating layers to each other; and
external electrodes formed on end surfaces of the multilayer body and connected to the internal coil part,
wherein a length-width cross sectional area of an upper or lower portion of the multilayer body in a thickness direction is wider than a length-width cross sectional area of a central portion of the multilayer body in the thickness direction.

9. The multilayer inductor of claim 8, wherein when a width of the central portion of the multilayer body in the thickness direction is W1 and a width of the upper or lower portion of the multilayer body in the thickness direction is W2, 1.01≦W2/W1≦1.3 is satisfied.

10. The multilayer inductor of claim 8, wherein when a length of the central portion of the multilayer body in the thickness direction is L1 and a length of the upper or lower portion of the multilayer body in the thickness direction is L2, 1.01≦L2/L1≦1.3 is satisfied.

11. The multilayer inductor of claim 8, wherein insulating layers included in the upper and lower portions of the multilayer body in the thickness direction and insulating layers included in the central portion of the multilayer body in the thickness direction have different sintering shrinkage rates.

12. The multilayer inductor of claim 8, wherein sintering shrinkage rates of the insulating layers disposed in the multilayer body are increased in a direction toward a center of the multilayer body in the thickness direction.

13. A method of manufacturing a multilayer inductor, the method comprising:
preparing a plurality of insulating sheets having different sintering shrinkage rates;
forming internal coil patterns on the insulating sheets;
forming an insulating sheet multilayer body by stacking the insulating sheets having the internal coil patterns formed thereon; and
forming a multilayer body by sintering the insulating sheet multilayer body,
wherein, in the forming of the insulating sheet multilayer body, insulating sheets having a relatively high sintering shrinkage rate are disposed adjacent to a central portion of the insulating sheet multilayer body in a thickness direction as compared with insulating sheets having a relatively low sintering shrinkage rate.

14. The method of claim 13, wherein when a ratio of the width of the sintered insulating sheets disposed in the central portion of the insulating sheet multilayer body in the thickness direction to the width of the non-sintered insulating sheets disposed in the central portion of the insulating sheet multilayer body in the thickness direction is S1, and a ratio of the width of the sintered insulating sheets disposed in the upper or lower portion of the insulating sheet multilayer body in the thickness direction to the width of the non-sintered insulating sheets disposed in the upper or lower portion of the insulating sheet multilayer body in the thickness direction is S2, 1.01≦S2/S1≦0.3 is satisfied.

15. The method of claim 13, wherein a length-width cross sectional area of an upper or lower portion of the multilayer body in the thickness direction is wider than a length-width cross sectional area of a central portion of the multilayer body in the thickness direction.

16. A board having a multilayer inductor, the board comprising:
a printed circuit board on which first and second electrode pads are disposed; and
a multilayer inductor mounted on the printed circuit board,
wherein the multilayer inductor includes:
a multilayer body in which a plurality of insulating layers are stacked and of which a thickness is greater than a width; and
an internal coil part formed by electrically connecting a plurality of internal coil patterns disposed on the plurality of insulating layers to each other,
side surfaces of the multilayer body opposing each other in a width direction are concave.
